(19) United States
(12) Patent Application Publication
(10) Pub. No.: US 2019/0186045 A1
(43) Pub. Date: Jun. 20, 2019

(54) DEVICE FOR GROWING SILICON CARBIDE OF SPECIFIC SHAPE

(71) Applicant: NATIONAL CHUNG SHAN INSTITUTE OF SCIENCE AND TECHNOLOGY, TAOYUAN CITY (TW)

(72) Inventors: BANG-YING YU, TAOYUAN CITY (TW); HSUEH-I CHEN, TAOYUAN CITY (TW); DAI-LIANG MA, TAOYUAN CITY (TW); CHENG-JUNG KO, TAOYUAN CITY (TW)

(21) Appl. No.: 15/904,694

(22) Filed: Feb. 26, 2018

(30) Foreign Application Priority Data
Dec. 18, 2017 (TW) 106144324

(51) Int. Cl. C30B 35/00; C30B 29/36; C23C 16/32; C23C 14/06

(52) U.S. Cl. CPC C30B 35/007; C23C 14/0635; C23C 16/325; C30B 29/36

(57) ABSTRACT

A device for growing a carbide of specific shape includes (A) a crucible; (B) a raw material source zone where a SiC raw material precursor is accessible; (C) a deposition zone where SiC is grown; (D) a gas temperature gradient control zone characterized by a temperature gradient; (E) a current deposition carrier disposed within the deposition zone and characterized by at least one repetition of a succession of one or at least two specific shapes of the current deposition carrier; and (F) a heating component for heating the SiC raw material precursor to turn it into gas molecules, so as to effectuate its deposition on the current deposition carrier.

### CROSS-REFERENCE TO RELATED APPLICATION

This non-provisional application claims priority under 35 U.S.C. § 119(a) on Patent Application No(s). 106144324 filed in Taiwan, R.O.C. on Dec. 18, 2017, the entire contents of which are hereby incorporated by reference.

### FIELD OF THE INVENTION

The present invention relates to crucible devices and, more particularly, to a device for growing a carbide of specific shape.

### BACKGROUND OF THE INVENTION

Technological advancements and high standard of living together bring the trend of 3C hi-tech electronic products toward light weights, compactness and versatility. Hence, SiC and group III nitrides (GaN, AlN) developed to become semiconductor materials in the manufacturing of various electronic devices. In this regard, they not only have high physical strength and high chemical inertness, but also manifest excellent electronic characteristics, including high hardness, high breakdown critical electric field strength, wide band gaps, high saturation drift velocity, and high thermal stability.

Semiconductor manufacturers employ physical vapor transport (PVT) and physical vapor deposition (PVD) to SiC crystals as well as manufacture chips by mass production. PVT involves subliming powder of SiC in a muffle heating zone and speeding up movement of the gaseous SiC to a seed crystal by temperature gradient to undergo crystal growth process. Quality of crystals grown by PVT depends on SiC raw material, purity and dimensions; hence, the SiC raw material must be placed under control in order to ensure the quality of SiC crystal growth.

Raw materials of SiC are most commonly produced by Acheson method, which involves mixing quartz (silicon dioxide) and coke (carbon) in a muffle and then heating the mixture to a temperature above 2000° C., so as to form coarse SiC powder. However, samples resulting from Acheson method often contain residual reactants. Hence, it is generally necessary to heat the samples above 600˜1200° C. in order to remove residual carbon by oxidation, remove residual metallic oxide or silicon dioxide by a pickling process, and grind the samples into powder, so as to obtain SiC powder of different dimensions by grading. Therefore, the SiC raw material thus produced contains so much impurity that purification thereof is required before use; however, the required purification is restricted by the production process, and thus the purified raw material does not have sufficiently high purity in order to be applied to the SiC crystal growth process.

Another method of producing SiC raw material is chemical vapor deposition (CVD). CVD entails introducing carbon and silicon precursors or gaseous raw material into a high-temperature cavity to undergo a chemical reaction and produce SiC. The cavity contains a graphite pipe. The SiC reactants deposit on the graphite pipe functioning as a reaction end. Then, the samples, which have reacted and deposited, are heated to 600˜1200° C. Afterward, the graphite pipe is removed by oxidation, whereas the samples are ground into particles. Finally, the particles are graded to obtain SiC raw material of different dimensions. Although the SiC raw material produced by CVD features high purity and low nitrogen concentration because of the gaseous reaction, the ground raw material is of different dimensions; as a result, high-quality SiC raw material thus produced is not of uniform dimensions.

CN102597339A (citation 1) discloses a method of producing SiC crystal by synthesizing SiC raw material by PVT, subliming the SiC raw material repeatedly to reduce aluminum content (<100 ppm) and iron content (<0.1 ppm) in the SiC, grinding the SiC crystal and pickling it.

CN103708463A (citation 2) discloses a production method of one-kilogram-class high-purity SiC powder as follows: placing a graphite crucible in a CVD furnace, introducing methane gas into the graphite crucible, so as for carbon film to be formed on the surface of the graphite crucible at a temperature of 1000˜1200° C.; mixing silicon powder and carbon powder before placing the mixture in the carbon film-plated graphite crucible, heating the graphite crucible to 1800˜2000° C. in a high-purity argon environment for 2˜10 hours before cooling it down to room temperature, so as to form a dense layer of SiC on the inner wall of the graphite crucible; mixing silicon powder and carbon powder, placing the mixture in the SiC-plated graphite crucible, placing the graphite crucible in a heating tube, placing the heating tube in a frequency-induction heating furnace, degassing the system to remove nitrogen and oxygen gas, heating the graphite crucible to a temperature of 800˜1100° C., purging highly pure argon gas, helium gas, or a mixture of argon and hydrogen gas to the graphite crucible, increasing the temperature of the graphite crucible slowly to a reacted temperature of 1500˜1900° C., soaking for 2˜24 hours, and decreasing the aforesaid temperature to room temperature, so as to obtain one-kilogram-class high-purity SiC powder.

However, the method disclosed in citation 1 requires grinding the SiC crystal repeatedly and thus readily causes secondary contamination to the detriment of production yield. The contamination thus caused must be eliminated by oxidation and pickling in order to obtain high-purity SiC raw material, thereby leading to a waste of time and high processing costs. The method disclosed in citation 2 requires plating the graphite crucible with carbon film and SiC layer in sequence. Furthermore, citation 2 does not disclose how to control dimensions of high purity SiC powder. Hence, citation 2 is disadvantaged by complicated steps of production, low efficiency, and failure to control the dimensions of high purity SiC powder.

As described before, the dimensions of the high purity SiC raw material produced by chemical vapor deposition (CVD) or physical vapor transport (PVT) remain uncontrolled. In addition, the high purity SiC raw material thus produced requires grinding and thus is susceptible to secondary contamination to the detriment of production yield. Furthermore, owing to the contamination arising from the grinding process, the contaminated SiC raw material must undergo oxidation and pickling in order to turn into high-purity SiC raw material, thereby leading to low time efficiency and high processing costs.

### SUMMARY OF THE INVENTION

In view of the aforesaid drawbacks of the prior art, the present invention is characterized in that a reaction cavity contains a current deposition carrier (hereinafter referred to as the raw material box) operating in a flow guiding mode, such as a graphite device, and a growth chamber (muffle) for internal thermal field and flow field control to obtain grinding-free SiC raw material, so as to circumvent conventional issues, such as secondary contamination and high raw material processing costs, but obtain SiC raw material of specific dimensions, augment the surface area for deposition of the SiC raw material. Last but not least, the SiC raw material produced by the present invention is applicable to any SiC monocrystalline growth process.

In general, production of SiC raw material by CVD can be effectuated in various ways, that is, it involves selectively using a gaseous mixture of silane (SiH₄) and methane or a gaseous mixture of SiCl₄ and methane, using methylchlorosilane (MTS) as an initiator directly, or using hydrogen gas or an inert gas as a carrier gas. Using MTS as an initiator does not require controlling the carbon/silicon ratio and thus is the easiest way to produce SiC raw material, as illustrated by Eq. (1) below.

CH₃SiCl₃→SiC+3HCl Eq. (1)

Eq. (1) illustrates thermal decomposition of MTS, forming products, namely SiC and hydrogen chloride (HCl). HCl is highly soluble in water and thus its filtering substrate is water, wherein whatever acidic gas contamination environment is eliminated by a neutralization apparatus.

By contrast, production of SiC raw material by PVT can be effectuated by heating a graphite crucible (which is enclosed by a thermally insulating material) with a heating device, defining a cool zone, defining a hot zone, placing SiC raw material at the bottom of the graphite crucible, and purging an inert gas (as a carrier gas) into a muffle during a processing of purifying the SiC raw material. As soon as the thermal field environment meets a criterion of sublimation of SiC, the SiC raw material decomposes into gaseous Si, Si₂C, SiC₂ and SiC. Then, the gases are transferred to the cool zone of the graphite crucible to undergo a reaction and thus form SiC crystal. The aforesaid reactions are illustrated by Eq. (2)˜(4) below.

SiC₂₍ₛ₎+Si(g)↔SiC₍ₛ₎ Eq. (2)

SiC_{2(g)}↔Si_{(g)}+2C₍ₛ₎ Eq. (3)

3Si_{(g)}+SiC_{2(g)}↔2Si₂C_{(g)} Eq. (4)

The present invention provides a device of producing SiC raw material, comprising: (A) a crucible; (B) a raw material source zone where a SiC raw material precursor is available; (C) a deposition zone where SiC is grown; (D) a gas temperature gradient control zone characterized by a temperature gradient; (E) a current deposition carrier disposed within the deposition zone and characterized by at least one repetition of a succession of one or at least two specific shapes of the current deposition carrier; and (F) a heating component for heating the SiC raw material precursor to turn it into gas molecules, so as to effectuate its deposition on the current deposition carrier.

The device of producing SiC raw material according to the present invention dispenses with a grinding step and thus circumvents conventional issues, such as secondary contamination and high raw material processing costs. The present invention is advantageous in that the device of the present invention produces SiC raw material of specific dimensions by a current deposition carrier with a deposition surface. Last but not least, the SiC raw material thus produced is applicable to any SiC growing process.

In a preferred embodiment, PVT involves placing the SiC raw material precursor at a relatively hot end and using the deposition zone as a relatively cool end such that the thermal field in step (D) features a temperature gradient. The temperature gradient is 2.5˜100° C./cm, preferably 20˜80° C./cm.

Given the thermal field with the temperature gradient and the current deposition carrier with a specific channel, it is feasible to control the heating device's temperature, thermal field, atmosphere and pressure and deposit gas molecules of a pre-plated substance (SiC raw material precursor) on the current deposition carrier disposed in the deposition zone by chemical vapor deposition (CVD) or physical vapor transport (PVT).

In a preferred embodiment, the current deposition carrier of the deposited SiC bulk material is burnt and eliminated by a high-temperature oxidation method. Preferably, the high-temperature oxidation method is carried out at a temperature of above 900° C., preferably 900˜1200° C.

By burning and eliminating the current deposition carrier high-temperature oxidation directly, it is not necessary to perform the additional step of separating the SiC raw material from the current deposition carrier.

In a preferred embodiment, the base of the current deposition carrier is made of graphite paper, graphite blanket, carbon-carbon material, or graphite. The carbon-containing high-temperature material is graphite paper, graphite blanket, carbon-carbon material, highly isotropic graphite, or graphite bulk material. Preferably, the current deposition carrier has therein a baffle. The baffle is made of carbon-carbon composite, isotropic graphite, anisotropic graphite, graphite bulk material or high-temperature-resistant metallic carbide. Preferably, the deposition surface is of a shape defined as follows: 1. repetitions of a succession of triangles or polygons; 2. repetitions of a succession of round or annular shapes; 3. repetitions of a succession of cylindrical shapes or pyramidal shapes.

The current deposition carrier made of the carbon-containing high-temperature material not only enables the SiC raw material to deposit without being contaminated, but also increases the surface area of deposition of the SiC raw material. With the current deposition carrier having therein a baffle, the positions at which SiC raw material of specific dimensions deposits is well-defined so as to facilitate the deposition of the SiC raw material of specific dimensions. By changing the shape of the deposition surface, it is feasible to SiC raw material of different shapes and dimensions. The shape of the deposition surface is designed according to the raw material shapes and dimensions.

In a preferred embodiment, the current deposition carrier is disposed within a deposition zone dedicated to PVT or CVD.

The device of producing SiC raw material according to the present invention overcomes the drawbacks of conventional chemical vapor deposition (CVD) or conventional physical vapor transport (PVT), dispenses with a grinding step, and controls the dimensions of the SiC raw material thus produced.

The present invention involves placing a specific current deposition carrier (raw material box) in a growth environment of SiC raw material and preferably involves growing SiC raw material of high purity, specific shapes and dimensions by chemical vapor deposition (CVD) or physical vapor transport (PVT). The main production process is controlled stage by stage with the channels of the current deposition carrier and by controlling the heat transfer, mass transfer and thermal field tendency inside the muffle; hence, not only do vertical and lateral thermal radiation temperature differences and vertical temperature gradient in a growth chamber fall into appropriate ranges, but sublimed gas or material source of the decomposed SiC raw material precursor also nucleates and grows steadily on the current deposition carrier to form highly dense, high-purity SiC bulk material of specific shapes and dimensions, thereby facilitating subsequent growth of raw material and current deposition carrier and separation thereof by a high-temperature oxidation method, so as to reduce contamination.

The production device of the present invention is effective in producing SiC raw material of high purity and specific dimensions without a grinding process and a pickling process to not only reduce secondary contamination otherwise caused by the grinding process, but also efficiently reduce the cost incurred in purification of SiC raw material. Last but not least, the SiC raw material thus produced by the present invention is applicable to any SiC monocrystalline growth process.

### BRIEF DESCRIPTION OF THE DRAWINGS

FIG. 1 is a schematic view of a production device disclosed according to the present invention and adapted to apply a production method of the present invention to CVD;

FIG. 2 is a schematic view of another production device disclosed according to the present invention and adapted to apply the production method of the present invention to PVT;

FIG. 3A is a top view of a current deposition carrier according to an embodiment of the present invention;

FIG. 3B is a perspective view of the current deposition carrier according to an embodiment of the present invention;

FIG. 4A is a top view of the current deposition carrier according to another embodiment of the present invention;

FIG. 4B is a perspective view of the current deposition carrier according to another embodiment of the present invention;

FIG. 5A is a schematic view of an empty graphite crucible dedicated to CVD;

FIG. 5B is a schematic view of a deposition zone with two graphite crucibles for use with the current deposition carrier according to the present invention;

FIG. 5C is a schematic view of the deposition zone with four graphite crucibles for use with the current deposition carrier according to the present invention; and

FIG. 6 is a schematic view of polycrystalline, high-purity, large-sized (dimensions greater than 1 cm) SiC raw material produced by the production method of the present invention.

### DETAILED DESCRIPTION OF THE PREFERRED EMBODIMENTS

The features and advantages of the present invention are detailed hereinafter with reference to specific embodiments. The detailed description is intended to enable a person skilled in the art to gain insight into the technical contents disclosed herein and implement the present invention accordingly.

The present invention involves producing SiC raw material of high purity, specific shapes and dimensions by a current deposition carrier (raw material box) with specific channels and great surface area, but dispensing with a grinding process. In a preferred embodiment of the present invention, the current deposition carrier (raw material box) is placed within a deposition zone, then a SiC raw material precursor is contained in a container or a SiC raw material precursor material source is introduced into a high-purity source zone of the thermal field device by a carrier gas, and finally the SiC raw material precursor, whether solid or liquid, is sublimed or decomposed into gas molecules by a heating device (heat source) with a temperature gradient and a thermal field. By controlling the temperature, thermal field, atmosphere and pressure in the heating device, it is feasible to deposit gas molecules of a pre-plated substance (SiC raw material precursor) on the current deposition carrier in a deposition zone by chemical vapor deposition (CVD) or physical vapor transfer (PVT) at a deposition speed of 10 um/hr˜1000 um/hr for 24 hours. The deposited SiC raw material is of dimensions of at least 1 cm. The current deposition carrier is removed by a high-temperature oxidation method. Hence, the present invention meets the specification requirements of high-purity SiC raw material.

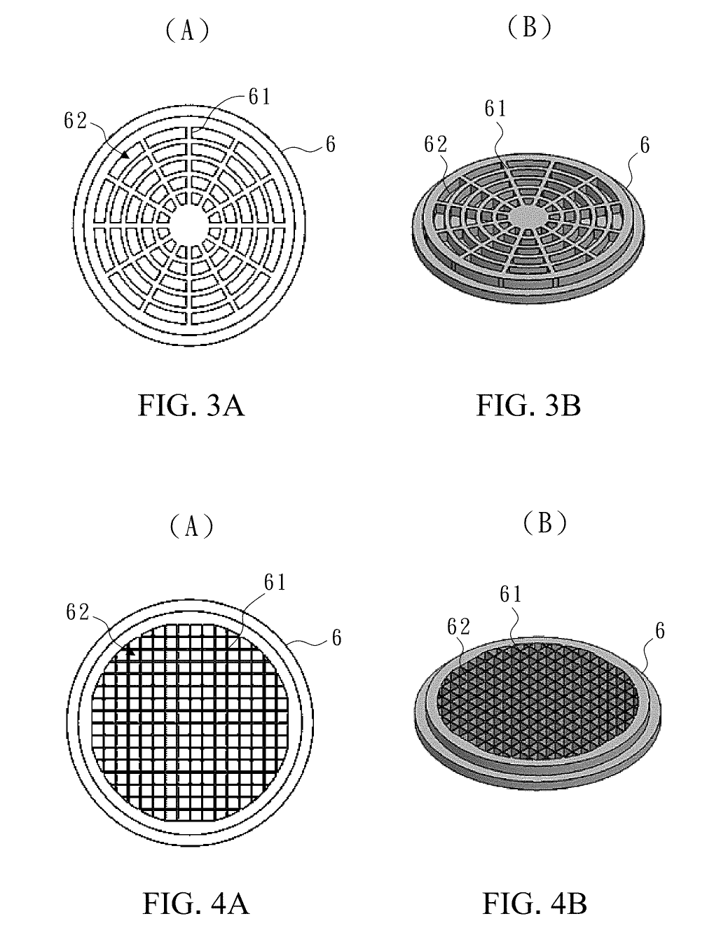

Referring to FIG. 3 and FIG. 4 for the following. FIG. 3A is a top view of the current deposition carrier of the present invention an embodiment. FIG. 3B is a perspective view of the current deposition carrier according to an embodiment of the present invention. FIG. 4A is a top view of the current deposition carrier according to another embodiment of the present invention. FIG. 4B is a perspective view of the current deposition carrier according to another embodiment of the present invention.

As shown in FIG. 3A and FIG. 3B, the current deposition carrier 6 of the present invention comprises a deposition surface 62 and baffles 61. The current deposition carrier 6 comprises round, annular channels. The round, annular channels are separated by the baffles 61. Therefore, SiC raw material of specific dimensions is formed on the deposition surface 62.

As shown in FIG. 4A and FIG. 4B, the current deposition carrier 6 of the present invention comprises a deposition surface 62 and the baffles 61. The current deposition carrier 6 is characterized in that the baffles 61 together demarcate and define square channels. Therefore, SiC raw material of specific dimensions is formed on the deposition surface 62.

The shapes of the deposition surface 62 fall into categories as follows: 1. repetitions of a succession of triangles or polygons; 2. repetitions of a succession of round, annular shapes; 3. repetitions of a succession of cylindrical shapes or pyramidal shapes; 4. repetitions of a succession of patterns of irregular shapes, but the present invention is not limited thereto, and thus the shapes of the deposition surface 62 may be designed according to the required shape and dimensions of the raw material.

The materials which the current deposition carrier 6 is made of fall into categories as follows: the base is made of carbon-containing high-temperature material, such as carbon-carbon composite, isotropic graphite, anisotropic graphite or graphite bulk material, but the present invention is not limited thereto. The carbon-containing high-temperature material has impurity content which is preferably less than 200 ppm and dimensions (length of sides) or diameter which is preferably less than 50 cm, but the present invention is not limited thereto.

The materials which the baffles 61 are made of fall into categories as follows: carbon-containing material, such as carbon-carbon composite, isotropic graphite, anisotropic graphite or graphite bulk material, but the present invention is not limited thereto. The carbon-containing material has impurity content which is preferably less than 200 ppm, but the present invention is not limited thereto. The baffles 61 are also made of high-temperature-resistant metallic carbide, such as WC, TaC or NbC, but the present invention is not limited thereto.

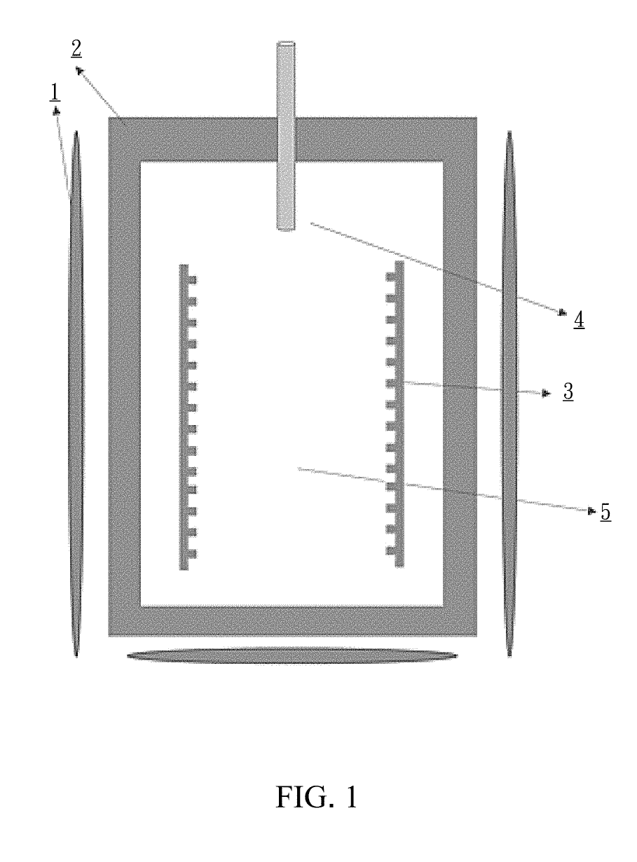

Referring to FIG. 1, there is shown a schematic view of a production device of the present invention, that is, a schematic view of a device whereby a production method of the present invention is applied to CVD. As shown in FIG. 1, the production device of the present invention comprises a crucible 21, a deposition zone 22, a raw material source zone 23, a gas temperature gradient control zone 24, a heating component 25 and a current deposition carrier 26.

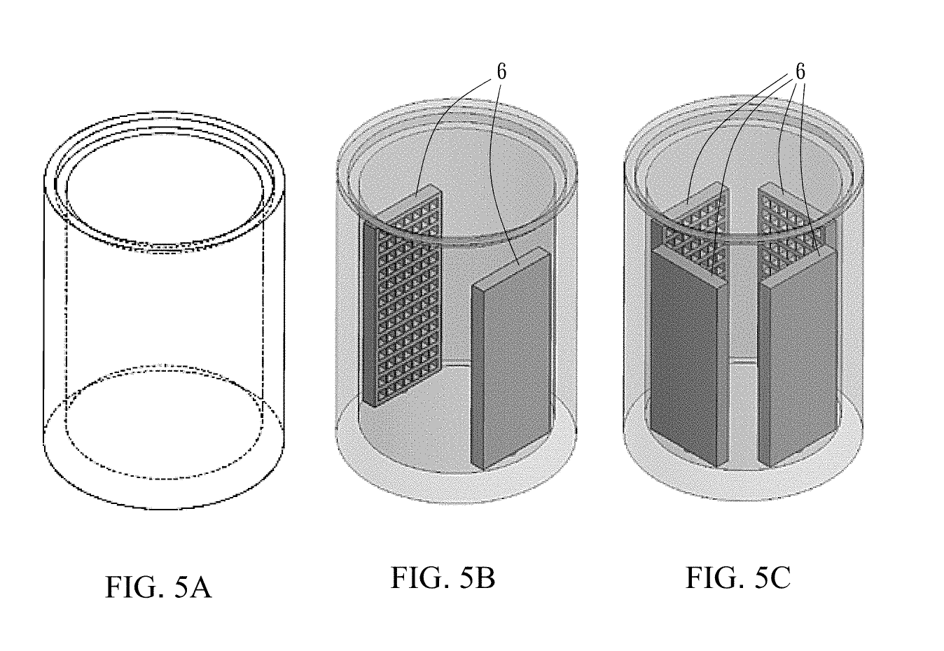

The gas temperature gradient control zone 24 comprises a deposition zone 22 and a raw material source zone 23. The current deposition carrier 26 is disposed within the deposition zone 22. For further details about how the current deposition carrier 26 is disposed within the deposition zone 22, refer to FIG. 5.

FIG. 5A is a schematic view of an empty graphite crucible dedicated to CVD. FIG. 5B is a schematic view of a deposition zone with two graphite crucibles (growth chambers) for use with the current deposition carrier according to the present invention. FIG. 5C is a schematic view of the deposition zone with four graphite crucibles (growth chambers) for use with the current deposition carrier according to the present invention. As shown in FIG. 5A, the current deposition carrier 6 of the present invention is absent from the graphite crucible; hence, FIG. 5A merely shows a conventional graphite crucible for use in CVD. As shown in FIG. 5B, the current deposition carrier 26 may be disposed at two opposite positions on the lateral side (deposition zone 22) of the graphite crucible, for example, above or below the lateral side (deposition zone 22) of the graphite crucible. As shown in FIG. 5C, the current deposition carrier 26 may be disposed at four opposite positions on the lateral side (deposition zone 22) of the graphite crucible, for example, on top of, below, on the left, or on the right of the lateral side of the graphite crucible. The present invention is not restrictive of the number of the current deposition carrier 26 disposed within the deposition zone 22 and the positions at which the current deposition carrier 26 is disposed within the deposition zone 22.

The heating component 25 provides a thermal field whereby the SiC raw material precursor disposed within the raw material source zone 23 decomposes and deposits on the current deposition carrier 26. Upon deposition of the SiC raw material precursor, the current deposition carrier 26 is removed, thereby obtaining the SiC raw material.

In a preferred embodiment, the heating component 25 is controlled to provide a thermal field whereby not only is a gas temperature gradient control zone 24 formed in the crucible 21, but a gas temperature gradient control zone 24 is also formed between the raw material source zone 23 and the deposition zone 22 (or current deposition carrier 26).

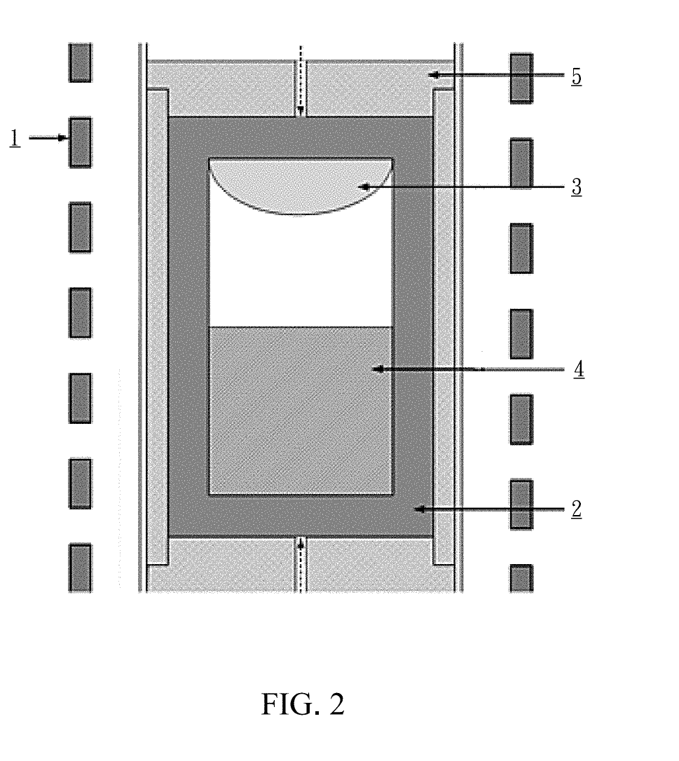

Referring to FIG. 2, there is shown a schematic view of another production device disclosed according to the present invention and adapted to apply the production method of the present invention to PVT. As shown in FIG. 2, the production device of the present invention comprises a crucible 11, a deposition zone 12, a raw material source zone 13, a gas temperature gradient control zone 14, a heating component 15 and a thermally insulating material 16.

Both the device for applying the production method of the present invention to PVT and the production device disclosed in the present invention and applied to CVD involve placing the current deposition carrier 6 in the deposition zone 12. The present invention is not restrictive of the positions at which the current deposition carrier 6 is disposed in the deposition zone 12 and the number of the current deposition carrier 6 disposed in the deposition zone 12.

The device for applying the production method of the present invention to PVT is described below. In a preferred embodiment, like the production device disclosed in the present invention and applied to CVD, the device for applying the production method of the present invention to PVT involves controlling the heating component 15 to provide a thermal field such that not only is a gas temperature gradient control zone 14 formed in the crucible 11, but a gas temperature gradient control zone 14 is also formed between the raw material source zone 13 and the deposition zone 12 (or the current deposition carrier 6). For instance, the temperature gradient control zone 14 has a temperature gradient, whereas the raw material source zone is a relatively hot end, and the deposition zone is a relatively cool end, so as to form a temperature gradient.

The temperature of the thermal field is preferably 900˜2300° C. and most preferably 1600° C.˜2300° C. The temperature gradient is preferably 2.5˜100° C./cm and most preferably 20˜80° C./cm.

The specific embodiment of the present invention is described below.

### Embodiment

In this embodiment, the method of producing SiC raw material of high purity and specific dimensions is PVT and is effectuated by the device illustrated by FIG. 2 and comprises the steps of: (A) providing a current deposition carrier 6 (round, annular raw material box, referring to FIG. 3); (B) placing the current deposition carrier 6 (raw material box) in a deposition zone 12 on top of a crucible 11; (C) placing a SiC raw material precursor (not shown) in a raw material source zone 13 below the growth chamber; (D) providing a thermal field; and (E) removing the current deposition carrier 6. Preferably, step (D1) of introducing a gas and step (D2) of controlling a heat source take place between step (D) and step (E). The steps are described below.

(A) Provide a current deposition carrier 6 (raw material box, as shown in FIG. 3): the current deposition carrier 6 is made of isotropic graphite with impurity less than 10 ppm. The deposition surface of the raw material box is round and annular, and the raw material box is of a diameter of 200 mm. Graphite paper which is 1 mm thick is disposed in the raw material box to function as a partition for the current deposition carrier 6 (as shown in FIG. 3).

(B) Place the current deposition carrier 6 in a crucible 11: the crucible 11 used in step (B) is shown in FIG. 2. The current deposition carrier 6 is placed in the deposition zone 12 on top of the crucible 11. The surface of the current deposition carrier 6 is defined as the deposition surface 62 which the SiC raw material precursor deposits on.

(C) Place a SiC raw material precursor in a raw material source zone 13 in the growth chamber. The distance between the raw material source zone 13 and the current deposition carrier 6 is less than 15 cm, preferably equal to 8 cm.

(D) Provide a thermal field. As shown in FIG. 2, step (D) is as follows: the heating component 15 which encloses the crucible 11 provides a thermal field for the crucible 11, and the position of the heating component 15 is controlled such that the raw material source zone 13 which contains the SiC raw material precursor functions as a relatively hot end of the thermal field, and the deposition zone 12 (current deposition carrier 6) functions as a relatively cool end of the thermal field. The thermal field causes the solid SiC raw material precursor to sublime into gas molecules. Then, the gas molecules deposit on the deposition surface 62 of the current deposition carrier 6. The gas molecules deposit on the deposition surface 62 of the current deposition carrier 6 mainly by physical vapor transport (PVT) at a deposition speed of 500 μm/hr for 24 hours, achieving a deposition thickness of 1 cm. The temperature of the thermal field stands at 1600˜2300° C., and the thermal field has a temperature gradient of 20° C./cm or above.

(E) Remove the current deposition carrier 6 (raw material box). The current deposition carrier 6 (raw material box) is removed by a high-temperature oxidation method as follows: the high-temperature oxidation occurs at a temperature of 900˜1200° C., and the temperature is maintained for 0.5˜24 hours, preferably 10˜24 hours. Repeat step (E) 1˜10 times to burn and remove the current deposition carrier 6 (raw material box). At last, SiC raw material of specific dimensions and high purity (at least purity 5N) is produced.

In a preferred embodiment (hereinafter referred to as the variant embodiment), step (D1) of introducing a gas and step (D2) of controlling a heat source take place between step (D) and step (E).

(D1) Introducing a gas: step (D1) involves introducing a gas into the crucible 11, the gas thus introduced into the crucible 11 is an inert gas, such as purity 5N argon (Ar) gas, and functions as a carrier gas. Furthermore, the gas thus introduced in step (D1) is hydrogen, methane, or ammonia.

(D2) Controlling a heat source: after step (D1), step (D2) is performed to control the position of the heating component 15 such that thermal field defined in step (D) is maintained in the growth chamber, causing the solid SiC raw material precursor to sublime into gas molecules and the gas molecules to deposit on the deposition surface 62 in the current deposition carrier 6.

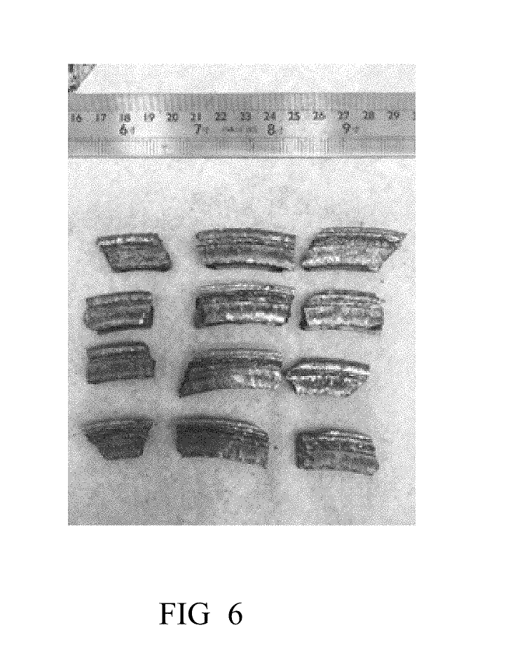

In this embodiment (variant embodiment), the appearance of the produced SiC raw material of high purity and specific dimensions is shown in FIG. 6, showing that it is polycrystalline SiC raw material of a diameter greater than 1 cm.

In conclusion, the present invention features a current deposition carrier (raw material box) with a specific channel and a great surface area as well as the resultant specific patterns and dimensions, with a view to producing high-purity SiC raw material without a grinding process.

The production device of the present invention is effective in producing SiC raw material of high purity and specific dimensions without a grinding process and a pickling process to not only reduce secondary contamination otherwise caused by the grinding process, but also efficiently reduce the cost incurred in purification of SiC raw material. Last but not least, the SiC raw material thus produced by the present invention is applicable to any SiC monocrystalline growth process.

The above embodiments are illustrative of the features and effects of the present invention rather than restrictive of the scope of the substantial technical disclosure of the present invention. Persons skilled in the art may modify and alter the above embodiments without departing from the spirit and scope of the present invention. Therefore, the scope of the protection of rights of the present invention shall be defined by the appended claims.

What is claimed is:

1. A device for growing a carbide of specific shape, the device comprising:
(A) a crucible;
(B) a raw material source zone where a SiC raw material precursor is accessible;
(C) a deposition zone where SiC is grown;
(D) a gas temperature gradient control zone characterized by a temperature gradient;
(E) a current deposition carrier disposed within the deposition zone and characterized by at least one repetition of a succession of one or at least two specific shapes of the current deposition carrier; and
(F) a heating component for heating the SiC raw material precursor to turn it into gas molecules, so as to effectuate its deposition on the current deposition carrier.

2. The device of claim 1, wherein the current deposition carrier comprises a base and a baffle.

3. The device of claim 2, wherein the base of the current deposition carrier is made of one of graphite paper, graphite blanket, carbon-carbon material, and graphite.

4. The device of claim 2, wherein the baffle of the current deposition carrier is made of one of graphite paper, graphite blanket, carbon-carbon material, graphite, and high-temperature-resistant metallic carbide, including WC, TaC or NbC.

5. The device of claim 1, wherein the current deposition carrier is characterized by at least one repetition of a succession of round, annular shapes of the current deposition carrier.

6. The device of claim 2, wherein the current deposition carrier enables deposition of SiC.

7. The device of claim 6, wherein the current deposition carrier effectuates separation of carbide by a high-temperature oxidation method.

8. The device of claim 7, wherein the SiC thus produced is of purity greater than 5N.

9. The device of claim 1, wherein the current deposition carrier is disposed within a deposition zone dedicated to one of PVT and CVD.

10. The device of claim 7, wherein the high-temperature oxidation method is carried out at a temperature of 900-1200° C.
